(19) United States
(12) Patent Application Publication
(10) Pub. No.: US 2003/0082917 A1
(43) Pub. Date: May 1, 2003

(54) Method of fabricating vertical actuation comb drives

(76) Inventors: Dean A. Hopkins JR., San Jose, CA (US); Martin Lim, San Mateo, CA (US); Minyao Mao, Santa Rosa, CA (US)

Correspondence Address: COUDERT BROTHERS LLP, Third Floor, 600 Beach Street, San Francisco, CA, 94109, US

(21) Appl. No.: 10/039,380

(22) Filed: Oct. 26, 2001

(51) Int. Cl. H01L 21/302; H01L 21/461; H01L 21/311

(52) U.S. Cl. 438/694; 438/689

(57) ABSTRACT

A method of fabricating a vertical actuation comb drive first etches a cavity in a semiconductive wafer; then the comb structure is etched, and the fixed part of the structure is deformed by an induced strain, by techniques such as boron doping, by adding a metal layer or a fixed oxide, or a mechanical latch or an additional plate electrode. In a manner known in the art, application of a voltage across the fingers of the comb produces a deflection either tilting or a vertical movement in the moveable portion of the comb drive.

### INTRODUCTION

The present invention is directed to a method of fabricating a vertical actuation comb drive and more specifically where the comb drive is fabricated by a MEMS (Micro-electromechanical system) technique.

### BACKGROUND OF THE INVENTION

Vertical or torsional drive MEMS structures require a large gap necessitating high voltages or on the other hand, close spaced structures operable at low voltage, but with limited travel. In general, a comb drive in a MEMS structure consists of interdigitated portions which when an oscillating voltage is applied or a steady state voltage is applied across an individual fingers of the combs cause an attraction. This usually occurs in a single plane. Out of plane comb drives require precise control of gaps in structures made at different process steps. This forces multiple process steps with critical alignments. Such out of plane comb drives are sometimes termed vertically actuated comb drives.

### OBJECT AND SUMMARY OF INVENTION

A general object of the present invention to provide a method of fabrication of a vertical actuation comb drive.

In accordance with the above object, there is provided a method of fabricating a vertical actuation MEMS(micro-electromechanical system) structure comb drive comprising the following steps:

providing a semiconductive wafer;

etching a cavity in the wafer;

etching an interdigitated comb structure in the etched portion of the cavity one portion of the comb being relatively fixed and the other floating or pivoted; and

inducing strain in said fixed portion to partially deform it into said cavity whereby application of a voltage between said portions causes the floating or pivoted portion to move toward the deformed fixed portion.

### BRIEF DESCRIPTION OF DRAWINGS

FIG. 1 is a top plan view of an actuator embodying the present invention.

FIG. 2 is a side view of FIG. 1 in an unactuated condition.

FIG. 3 is a side view of FIG. 1 in an actuated condition.

FIG. 4 is a flow chart illustrating a fabrication step of the present invention.

FIG. 5 is a plan view of another embodiment of the invention.

FIG. 6 is a side view of FIG. 5 in an unactuated condition.

FIG. 7 is a side view of FIG. 5 in an actuated condition.

FIG. 8A-8D are side views illustrating the construction of the embodiment of FIG. 5.

FIG. 8E is a top view of FIG. 8D which is similar to a simplified showing of FIG. 5.

FIG. 9 is a side view of an alternative embodiment of wafer deformation.

FIG. 10 is a side view of another embodiment as in FIG. 9.

FIG. 11 is a simplified cross-sectional view of FIG. 10.

### DETAILED DESCRIPTION OF PREFERRED EMBODIMENTS

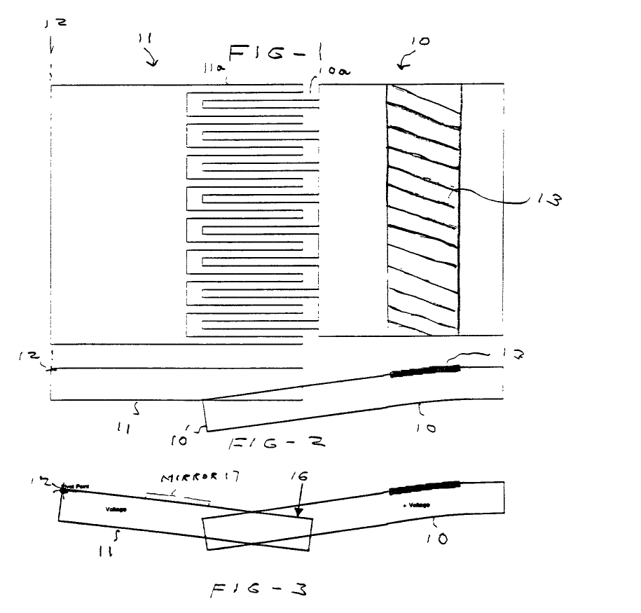

FIG. 1 illustrates a MEMS type of vertical actuation comb driver fabricated from a Simox type wafer which may be of any semiconductive type which includes a fixed portion 10 and a movable portion 11. In the embodiment shown in FIG. 1 the movable portion 11 is typically pivoted on the axis 12. Portion 11 has a comb type structure consisting of a number of fingers 11a and fixed structure 10 has a number of fingers 10a which the fingers are interdigitated with one another. Thus far, planar comb drives where application of a voltage between the fingers 10a and 11a cause planar movement are well known.

However, as best illustrated in FIG. 2, portion 10 has an induced strain area 12 overlaying the top surface of portion 10 which causes part of portion 10 to be deflected or deformed toward the position indicated at 10′; in other words, this is an affect in a vertical direction from the other portion 11. Thus, when a voltage is applied between wafer portions 10 and 11 a force indicated by the arrow 16 occurs because of the attraction for example of the plus voltage on portion 10 and the negative voltage on portion 11. The pivoted portion 11 is moved vertically downwardly toward the already deformed or deflected portion 10. Thus, for example, if a mirror 17 has been mounted on the wafer portion 11, this may serve to switch an optical beam path in a crossbar communications switching system.

The induced strain indicated as 13 and now referring to FIG. 4 may be induced by several different techniques. It may be by doping of the surface area of the wafer portion 10 by boron, applying a metal layer or applying a thick oxide. Other techniques are also possible.

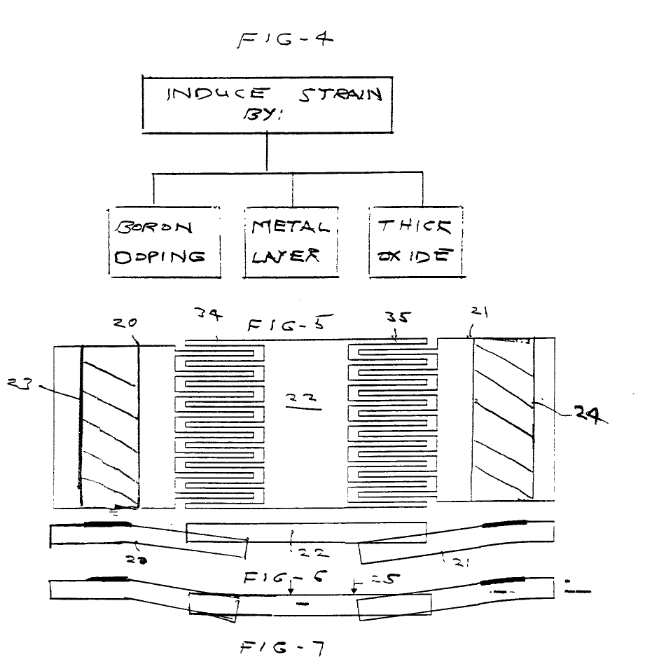

FIGS. 5, 6, and 7 show a second embodiment where a mirror image of the embodiment of FIG. 1 is duplicated to provide fixed stressed portions 20 and 21 having between them in an interdigitated manner a floating portion 22. Fixed portions 20 and 21 include an induced stressed portions 23 and 24 which as shown in FIG. 6 cause deformation equally on the left and right sides of the floating portion 22. As illustrated in FIG. 7, when the appropriate voltage difference is applied between floating portion 22 and the fixed portions 20 and 21, the movement of the floating portion is vertically downward as indicated by the arrows 25.

By the foregoing technique perfect up and down movement can be obtained. It is especially useful in, for example, a Fabry-Perot interferometer.

To summarize the operation of the embodiments of FIG. 1 and FIG. 5. FIG. 1 may be termed a toiesion type actuation device and FIG. 5 is a piston actuation type device.

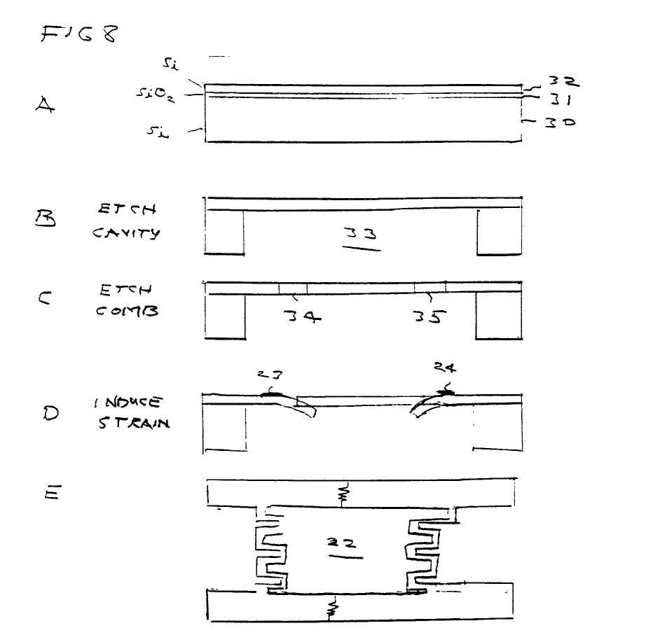

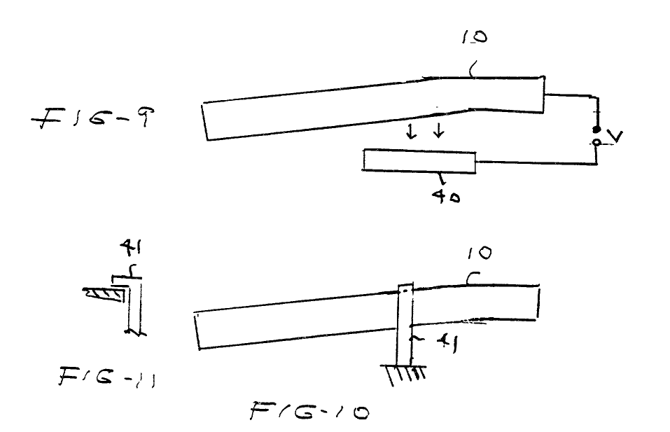

FIGS. 8A through 8E show the fabrication steps to produce specifically the actuator of FIG. 5 and is equally applicable to the actuator of FIG. 1. As illustrated in FIG. 8A, a silicon over insulator (SOI) type wafer is provided which is termed a SIMOX type wafer. Here there is a silicon base 30 with an insulator layer 31 (typically of silicon dioxide) and then another silicon layer 32. SIMOX type device is a formed by separation by implanted oxygen technique. But in general it is silicon on insulator (SOI) type wafer. Another suitable wafer is BESOI (Bonded Etched silicon over insulator). In the step of FIG. 8B, a cavity 33 is etched with the silicon dioxide layer 31 acting as an appropriate stop. Then in step 8C, a comb type structure illustrated in FIG. 5 and shown at 34 and 35 is produced. In FIG. 8D strain is induced as shown at 23 and 24 and the device is now complete as shown by the simplified top view of FIG. 8E which is of course similar to FIG. 5.

Other techniques of deforming wafer 10 are shown in FIGS. 9 and 10. In FIG. 9 a electrode plate 40 with permanent voltage, V, attracts wafer 10. In FIGS. 10 and 11 a mechanical L-shaped latch 41 pulls down the wafer.

Thus, a method of fabricating an improved vertical actuation MEMS structure comb drive has been provided.

What is claimed is:

1. A method of fabricating a vertical actuation MEMS(micro-electromechanical system) structure comb drive comprising the following steps:
providing a semiconductive wafer;
etching a cavity in said wafer; and
etching an interdigitated comb structure in the etched portion of said cavity one
portion of said comb being relatively fixed and the other floating or pivoted;
inducing strain in said fixed portion to partially deform it into said cavity whereby application of a voltage between said portions causes said floating on pivoted portion to move toward said deformed fixed portion.

2. A method as in claim 1 where said wafer is of the silicon over oxide type and said etching of said cavity is limited by said oxide.

3. A method as in claim 1 where said portion is floating and proving a second fixed portion between which said floating portion may be actuated for perfect up and down vertical movement.

4. A method as in claim 1 where said portion is pivoted only so that movement of said portion is tilting to provide a base for an optical mirror.

5. A method as in claim 1 where strain is induced by one of the following steps:
boron doping;
adding a metal layer;
adding a thick oxide;
providing an attractive electric field; and
mechanically latching said wafer.
